(19) United States
(12) Patent Application Publication
(10) Pub. No.: US 2026/0092884 A1
(43) Pub. Date: Apr. 2, 2026

(54) MULTIFUNCTIONAL SAMPLE STAGE FOR IN-SITU TESTING WITH TRANSMISSION ELECTRON MICROSCOPE AND ATOM PROBE TOMOGRAPHY

(71) Applicant: Institute of Geology and Geophysics, Chinese Academy of Sciences, Beijing (CN)

(72) Inventors: Xu TANG, Beijing (CN); Biwen WANG, Beijing (CN); Lixin GU, Beijing (CN); Qiuli LI, Beijing (CN); Jinhua LI, Beijing (CN)

(21) Appl. No.: 19/321,229

(22) Filed: Sep. 7, 2025

(30) Foreign Application Priority Data
Sep. 30, 2024 (CN) 2024113887479

(51) Int. Cl. G01N 23/2204; H01J 37/20; H01J 37/285

(52) U.S. Cl. CPC G01N 23/2204; H01J 37/20; H01J 37/285

(57) ABSTRACT

The disclosure relates to the technical field of micro-analysis of materials, and provides a multifunctional sample stage for in-situ testing with transmission electron microscope (TEM) and atom probe tomography (APT). The multifunctional sample stage includes: a support stage comprising a base body, the base body having a first-step tier and a second-step tier; a metal pressing plate, wherein a first portion of the metal pressing plate is fixed to the first-step tier, and a second portion of the metal pressing plate is engageable with a silicon wafer carrying specimens disposed on the second-step tier; and a sample mounting stage assembly, which comprises a concave sample stage and a convex fixing stage, is positionable on the second-step tier, wherein a metal support grid for carrying specimens can be fixed to the sample mounting stage assembly.

### TECHNICAL FIELD

The disclosure relates to the technical field of micro-analysis of materials, and in particular to a multifunctional sample stage for in-situ testing with transmission electron microscope and atom probe tomography.

### BACKGROUND

Atom probe tomography (abbreviated as APT) is an advanced instrument offering atomic-scale spatial resolution (˜0.2 nm) and parts-per-million (ppm)-level detection sensitivity, capable of identifying elemental species and isotopic information in materials and reconstructing three-dimensional (3D) spatial distributions of different elements. Currently, the application of APT has expanded from the field of highly conductive materials (metals, alloys, etc.) to semiconductors, inorganic materials, biological materials, and geological minerals, for revealing spatial distributions of light and heavy atoms, solute clusters, nano-precipitates, and dislocation cores in materials. Although the application of APT is relatively extensive, APT can only obtain compositional information of materials and cannot acquire microstructural and crystallographic information of materials. Therefore, it is difficult to establish correlations between composition and crystallographic structure as well as material properties (e.g., mechanical, optical, electrical, and magnetic properties) based solely on APT, thereby impeding material design and development.

Accordingly, in recent years, researchers have developed an in-situ testing technique combining transmission electron microscopy (abbreviated as TEM) and atom probe tomography (APT). The transmission electron microscopy is capable of resolving crystallographic structures and microstructures of materials, thereby enabling acquisition of comprehensive material characteristics including morphology, major composition, crystal structure, elemental valence states, atomic occupancy, and three-dimensional spatial distribution of elements through in-situ TEM-APT testing performed on the same specimen. Based on this, the technique is expected to reveal correlations among composition, crystallographic structure, and material properties.

The APT testing requires the specimen to possess a needle-shaped structure (approximately 100 nm in diameter). To meet this requirement, researchers worldwide have primarily developed two APT testing approaches.

Approach 1: primarily employed for conventional APT testing, the apparatus of Approach 1 includes an APT-specific T-shaped sample stage and a silicon wafer for mounting needle-shaped specimens. The corresponding testing method generally includes: bonding a prepared needle-shaped specimen to a silicon post using focused ion beam (FIB) technology, where the silicon posts are arranged in an array pattern on the surface of a silicon wafer (for example, the silicon wafer measures 7 mm in length and 3 mm in width); and mounting the silicon wafer onto the T-shaped sample stage for APT experiment, thereby enabling simultaneous APT analysis of multiple needle-shaped specimens. Furthermore, as disclosed in Chinese Patent Application (CN110987995A), an electrolytic polishing method is employed to electrolytically process metallic materials to fabricate needle-shaped structures for conventional APT testing.

Approach 2: primarily designed for in-situ TEM-APT testing of specimens, this approach has been relatively less reported in research. The apparatus employed mainly includes a detachable T-shaped sample stage and a crescent-shaped metal grid (as documented in: Zschiesche H. et al., Ultramicroscopy, 2019, 206:112807; Povstugar Ivan et al., Microscopy and Microanalysis, 2019, 1-10; Chinese Invention Patent CN110987995A). The corresponding testing method substantially includes: first bonding a prepared needle-shaped specimen to a crescent-shaped metal grid using focused ion beam (FIB) technology, then directly loading the crescent-shaped metal grid onto a TEM sample holder to perform TEM experiments; subsequently, after completing the TEM experiments, fixing the crescent-shaped metal grid carrying the needle-shaped specimen to a detachable T-shaped stage, installing the detachable T-shaped stage into an APT instrument, and performing APT three-dimensional reconstruction experiments; based on the above two sequential testing procedures, achieving in-situ characterization of the same specimen in different instruments.

It can be observed that the sample stages in both aforementioned approaches are designed for independent testing requirements. However, with the diversified development of testing demands and the need for cost reduction and efficiency improvement, the development of a sample stage apparatus capable of simultaneously performing conventional APT testing and in-situ TEM-APT testing has become particularly urgent to meet new technical requirements. Since the APT sample stage constitutes a precision apparatus, developing both aforementioned sample stage apparatuses simultaneously to accommodate conventional APT testing and TEM-APT testing would incur prohibitively high costs. More significantly, when the aforementioned detachable T-shaped sample stage is in its closed configuration, the contact surface exhibits a linear profile. This linear contact surface renders the installation and removal of ultrathin and fragile metal grids (having a mere 30 μm thickness) unstable, consequently inducing bending and damage to the APT needle-shaped specimens. Finally, the specimen holder of the sample stage disclosed in Chinese Invention Patent CN110987995A cannot mount the silicon wafer used for supporting needle-shaped specimens in conventional APT testing. Furthermore, a height discrepancy exists between the APT specimens supported by the crescent-shaped metal grid and the APT specimens clamped by copper tubes (prepared through electrochemical polishing), thereby preventing safe execution of APT experiments.

### SUMMARY

The present disclosure provides a multifunctional sample stage capable of performing both conventional APT testing and in-situ TEM-APT testing, where the multifunctional sample stage enables composition reconstruction analysis of multiple material regions as well as in-situ microscopic analysis, thereby revealing correlations among material composition, crystallographic structure, and material properties.

In view of this, the present disclosure provides a multifunctional sample stage for in-situ testing with transmission electron microscope and atom probe tomography. The sample stage includes: a support stage comprising a base body, the base body having a first-step tier and a second-step tier; a metal pressing plate, wherein a first portion of the metal pressing plate is fixed to the first-step tier, and a second portion of the metal pressing plate is engageable with a silicon wafer carrying specimens disposed on the second-step tier; and a sample mounting stage assembly, which comprises a concave sample stage and a convex fixing stage, is positionable on the second-step tier, where a metal support grid for carrying needle-shaped specimens can be fixed to the sample mounting stage assembly.

Through the configuration, the sample stage of the present disclosure achieves both conventional APT analysis and in-situ TEM-APT analysis.

Regarding the multifunctional sample stage for in-situ testing with transmission electron microscope and atom probe tomography, the sample mounting stage assembly includes: a concave sample stage having formed thereon at least one recessed mounting position, the concave sample stage including a vertical surface at a location corresponding to the recessed mounting position, where a metal support grid carrying specimens is positionable at the recessed mounting position adjacent to the vertical surface; and a convex fixing stage having formed thereon a protruding end engageable with the recessed mounting position, the protruding end can be inserted into the corresponding recessed mounting position to clamp the specimen-carrying metal support grid between the protruding end and the vertical surface.

The configuration enables reliable positioning of needle-shaped specimens mounted on the metal support grid in a test-ready state.

In the multifunctional sample stage, the concave sample stage and the convex fixing stage are fixedly connected by a second fastener.

The configuration ensures reliability of the sample mounting stage assembly.

Further, the concave sample stage and/or the convex fixing stage are fixedly connected to the second-step tier by a third fastener.

The configuration ensures reliability of the sample mounting stage assembly as a component of the sample stage.

It is to be understood that those skilled in the art may determine the structural configuration, quantity, and distribution pattern of the second/third fasteners on the sample mounting stage assembly according to actual requirements.

In the multifunctional sample stage, the recessed mounting position has a vertical cross-section comprising an inverted semicircle or an isosceles trapezoid, where the legs of the isosceles trapezoid are arc-shaped.

The configuration enables secure fixation of the sample mounted on the metal support grid to the sample mounting stage assembly.

In the multifunctional sample stage, the metal pressing plate includes a first pressing portion and a second pressing portion, where the first pressing portion is disposed on the first-step tier, and an end of the second pressing portion adjacent to the silicon wafer is lower than an end of the second pressing portion adjacent to the first pressing portion.

The configuration enables reliable pressing of the specimen-carrying silicon wafer by the second pressing portion. Those skilled in the art may determine the structural configurations of the first/second pressing portions and their integration into the metal pressing plate according to actual requirements, including but not limited to: identical or different structures between the portions, and fixed connection or integral formation between the portions.

Regarding the metal pressing plate, the second pressing portion includes a sloped surface portion and/or a curved surface portion.

The configuration provides possible structural configurations of the second pressing portion.

Regarding the aforementioned metal pressing plate, the first pressing portion is fixed to the first-step tier by a first fastener; and/or the support stage is provided with a limiting structure at a position corresponding to the first-step tier.

The configuration ensures positional reliability of the first pressing portion on the first-step tier through the limiting structure. Furthermore, similar to the aforementioned second/third fasteners, those skilled in the art may determine the structural configuration, quantity, and distribution pattern of the first fastener on the first pressing portion according to actual requirements.

Regarding the multifunctional sample stage, the sample stage includes a base column disposed at the bottom portion of the support stage, the base column being configured to engage with a sample holder of an APT instrument.

The configuration provides a possible structural configuration of the sample stage base body, where the support stage and the base column form a generally T-shaped structure, which may be referred to as a T-shaped support stage.

Further, the base column includes a first base column segment and a second base column segment arranged sequentially from top to bottom, a radial dimension of the first base column segment is greater than a radial dimension of the second base column segment; and/or the second base column segment has a circular or D-shaped cross-section.

The configuration provides possible structural configurations of the base column.

### BRIEF DESCRIPTION OF THE DRAWINGS

The preferred embodiments of the present disclosure are described below with reference to the accompanying drawings.

FIG. 1 shows a structural schematic diagram of the support stage in the multifunctional sample stage.

FIG. 2 shows a structural schematic diagram of the metal pressing plate in the multifunctional sample stage.

FIG. 3 shows an assembly schematic diagram of the support stage, metal pressing plate and loaded silicon wafer in the multifunctional sample stage.

FIG. 4 shows a structural schematic diagram of the concave sample stage in the sample mounting stage assembly of the multifunctional sample stage.

FIG. 5 shows a structural schematic diagram of the convex fixing stage in the sample mounting stage assembly of the multifunctional sample stage.

FIG. 6 shows an assembly schematic of the multifunctional sample stage equipped with a metal support grid.

FIG. 7 shows an electron micrograph of the silicon wafer.

FIG. 8 shows an enlarged schematic diagram of local area A in FIG. 7.

FIG. 9 shows an electron micrograph of the metal support grid in the multifunctional sample stage.

FIG. 10 shows an enlarged schematic diagram of local area B in FIG. 9.

### LIST OF REFERENCE NUMERALS

100. multifunctional sample stage for in-situ testing with transmission electron microscope and atom probe tomography;
1. support stage;
11. first-step tier; 12. second-step tier; 13. limiting structure;
2. metal pressing plate;
21. first pressing portion; 22. second pressing portion;
3. sample mounting stage assembly;
31. concave sample stage;
311. recessed mounting position; 312. vertical surface;
32. convex fixing stage;
321. protruding end;
41. first fastener; 42. second fastener;
51. first connection hole; 52. second connection hole; 53. third connection hole; 54.
fourth connection hole; 55. fifth connection hole; 56. sixth connection hole;
6. base column;
61. first base column segment;
62. second base column segment; 621. positioning surface;
200. silicon wafer; 201. silicon post;
300. metal support grid; 301. comb-shaped tooth;
401. first specimen; and 402. second specimen.

### DETAILED DESCRIPTION OF THE EMBODIMENTS

Preferred embodiments of the present disclosure will be described below with reference to the accompanying drawings. It should be understood by those skilled in the art that these embodiments are only used to explain the technical principles of the present disclosure, and are not intended to limit the protection scope of the present disclosure.

It should be noted that in the description of the present disclosure, the directional or positional terms such as “center”, “upper”, “lower”, “left”, “right”, “vertical”, “horizontal”, “inner”, and “outer” are based on the directions or positional relationships shown in the accompanying drawings. These terms are used solely for facilitating the description and do not indicate or imply that the described apparatus or elements must have specific orientations or be constructed and operated in specific orientations. Therefore, these terms should not be construed as limiting the present disclosure. Furthermore, the terms “first” and “second” are used for descriptive purposes only and should not be construed as indicating or implying relative importance.

Furthermore, it should be noted that in the description of the present disclosure, unless expressly specified and defined otherwise, the terms “mounting”, “arrangement” and “connection” should be interpreted broadly. For example, a connection may be a fixed connection, a detachable connection, or an integral connection; the connection may be a direct connection, an indirect connection through an intermediate medium, or an internal communication between two components. Those skilled in the art may understand the specific meanings of the aforementioned terms in the present disclosure according to specific circumstances.

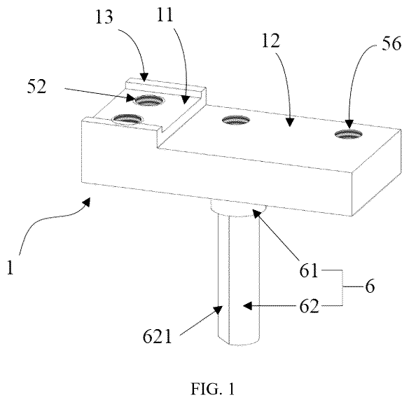

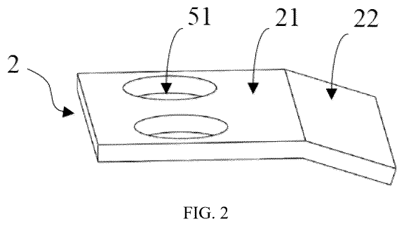

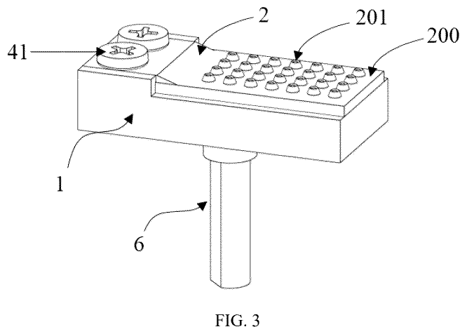

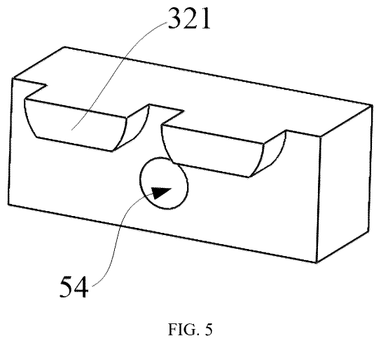

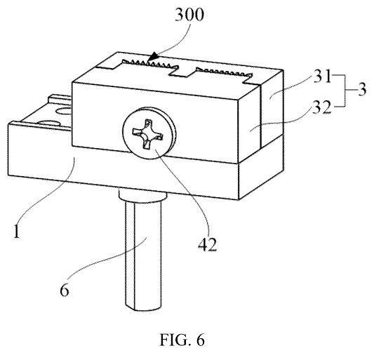

With primary reference to FIGS. 1-6, in one possible embodiment, the multifunctional sample stage for in-situ testing with transmission electron microscope and atom probe tomography 100 mainly includes a support stage 1, a metal pressing plate 2, and a sample mounting stage assembly 3. The support stage 1 includes a base body having a first-step tier 11 and a second-step tier 12, the first-step tier 11 having a height greater than the second-step tier 12. A silicon wafer 200 carrying a first specimen 401 for conventional APT testing is securely fixable to the support stage 1 through cooperation between the metal pressing plate 2 and the first/second-step tiers. The sample mounting stage assembly 3 is mountable to the support stage 1 at a position corresponding to the second-step tier 12, enabling a metal support grid 300 carrying a second specimen 402 for TEM-APT in-situ testing to maintain a stable testing configuration through the sample mounting stage assembly 3.

With primary reference to FIGS. 1-3, in one possible embodiment, the metal pressing plate 2 includes a first pressing portion 21 (alternatively referred to as a head portion) and a second pressing portion 22 (alternatively referred to as a tail portion). The first pressing portion 21 is disposed on the support stage 1 at a position corresponding to the first-step tier 11. The second pressing portion 22 has an end adjacent to the silicon wafer (right end in FIG. 1) that is lower than an end adjacent to the first pressing portion (left end in FIG. 1), thereby securely pressing the silicon wafer 200 carrying the first specimen through the second pressing portion. The second pressing portion may include a sloped surface, a curved surface, or a combination thereof. In the present example, the second pressing portion is substantially sloped.

In one possible embodiment, the support stage 1 is provided with a limiting structure 13 at a position corresponding to the first-step tier 11. When the first pressing portion 21 is disposed on the first-step tier, the limiting structure ensures positional reliability of the first pressing portion. In the present example, the limiting structure includes two limiting plates (disposed on opposite sides along the width direction of the silicon wafer) arranged on the first-step tier 11. The first pressing portion 21 is clamped between the two limiting plates in an assembled state. With the positional limitation provided by the limiting structure, the metal pressing plate may be fixed to the support stage 1 by a first fastener 41 such as a screw. The metal pressing plate 2 is provided with first connection holes 51 (e.g., a pair of through holes), while the support stage is provided with second connection holes 52 (e.g., a pair of blind holes or limiting holes) at positions corresponding to the first-step tier 11. Through engagement between the screws and the through holes/limiting holes, the metal pressing plate tightly presses the silicon wafer 200, thereby securely fixing the silicon wafer to the support stage 1.

Clearly, the combination of two limiting plates represents merely an exemplary embodiment of the limiting structure. Those skilled in the art may determine specific configurations of the limiting structure according to actual requirements, including but not limited to: replacing the limiting plates with structures having grooves/protrusions, or adding an auxiliary limiting structure such as a baffle/stop block between the two limiting structures (at a position abutting the head portion of the silicon wafer). Further, screws represent merely an exemplary embodiment of the first fastener. Alternative implementations may include, for example, using interference fits between taper pins and the first/second connection holes to achieve fixed connection between the metal pressing plate and the support stage.

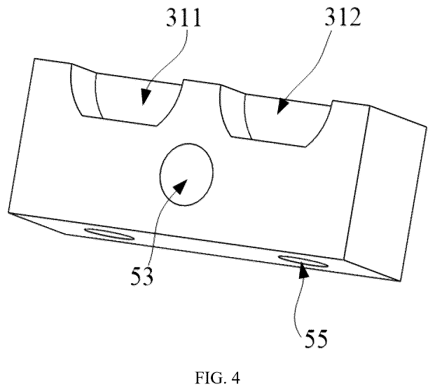

With primary reference to FIGS. 4-6, in one possible embodiment, the sample mounting stage assembly 3 includes cooperatively engaged concave sample stage 31 and convex fixing stage 32. The concave sample stage 31 is formed with at least one recessed mounting position 311 (e.g., a side-open groove), the concave sample stage 31 having a vertical surface 312 at a position corresponding to the recessed mounting position 311. The metal support grid 300 carrying the second specimen 402 is positionable at the recessed mounting position 311 adjacent to the vertical surface 312. The convex fixing stage 32 is formed with a protruding end 321 engageable with the recessed mounting position 311. Insertion of the protruding end 321 into the corresponding recessed mounting position 311 enables abutment against the metal support grid 300, thereby securely clamping the metal support grid 300 between the protruding end 321 and the vertical surface 312 and maintaining the metal support grid 300 in a test-ready configuration.

In one possible embodiment, the concave sample stage 31 and convex fixing stage 32 of the sample mounting stage assembly 3 are interconnected via a second fastener 42 such as screws, thereby forming an integrated assembly. In the present example, the concave sample stage 31 and convex fixing stage 32 are respectively provided with a third connection hole 53 and a fourth connection hole 54 corresponding to the screws.

In one possible embodiment, when the integrated assembly is positioned at the location corresponding to the second-step tier 12 of the support stage 1, the integrated assembly is fixedly connected to the support stage 1 via a third fastener (not shown) such as screws. The support stage 1 and the concave sample stage 31 are respectively provided with fifth connection holes 55 (a pair) and sixth connection holes 56, with the screws being inserted upward through the fifth connection holes 55 from the bottom of the support stage 1 into the sixth connection holes 56.

Clearly, the aforementioned structural configurations of the fasteners, their engagement methods with corresponding connection holes, and the structural types/quantities/distribution patterns of the connection holes are provided for exemplary purposes only. Those skilled in the art may flexibly select appropriate configurations according to actual requirements, including but not limited to: fasteners alternatively comprising dowel pins, bolts, or studs; and connection holes being respectively disposed on both the concave sample stage and convex fixing stage, or solely on the convex fixing stage when connecting the integrated assembly to the support stage 1.

In one possible embodiment, the multifunctional sample stage for in-situ testing with transmission electron microscope and atom probe tomography 100 is provided with a base column 6 at a bottom portion of the support stage 1. In the present example, the base column 6 includes a first base column segment 61 and a second base column segment 62 arranged sequentially from top to bottom. The first base column segment 61 has a relatively larger radial dimension primarily for enhancing stability of the support stage 1 when fixed to a sample holder, thereby ensuring safe APT specimen testing. The second base column segment 62 has a relatively smaller radial dimension primarily for connecting to the sample holder of an APT instrument.

In one possible embodiment, a positioning surface 621 may be machined on the second base column segment 62, effectively transforming the cylindrical structure into a generally D-shaped cross-sectional columnar structure. The configuration enables directional fixation between the second base column segment and the sample holder of the APT instrument when the sample holder is equipped with a positioning pin, through cooperative engagement between the positioning pin and the positioning surface of the second base column segment.

### I. Conventional APT Testing

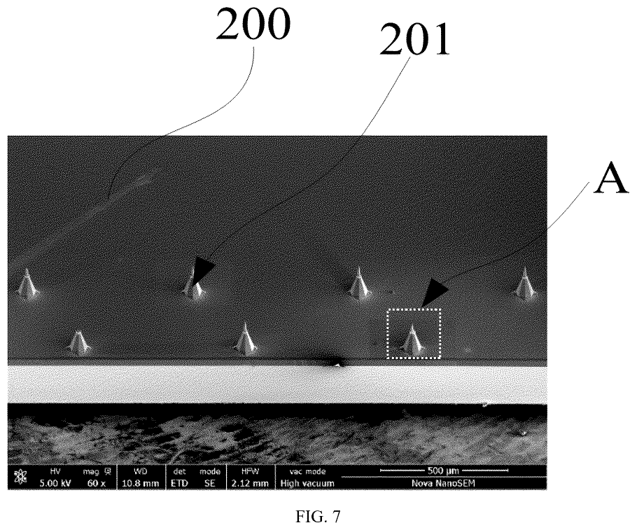

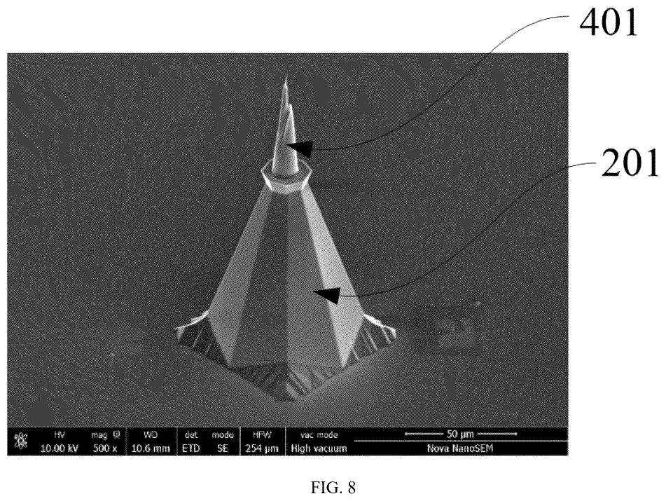

With primary reference to FIGS. 7-8, multiple silicon posts 201 are arranged in an array pattern on the surface of the silicon wafer 200. A first specimen (needle-shaped APT specimen) 401 prepared by FIB is disposed at a tip portion of the silicon posts 201.

When employing the aforementioned multifunctional sample stage 100 for conventional APT testing, the procedure includes the following steps:
first, placing the silicon wafer 200 carrying the first specimen 401 (needle-shaped APT specimen) on the second-step tier 12 of the support stage 1;
then, positioning the metal pressing plate 2 on the first-step tier 11 of the support stage 1, where a head portion of the metal pressing plate is clamped between two limiting structures; and
finally, securing the metal pressing plate to the support stage using a first fastener such as screws, thereby causing the metal pressing plate 2 to tightly press the silicon wafer 200 and reliably fix the silicon wafer 200 to the support stage 1.

When starting APT experiment, the second base column segment 62 is inserted into the sample holder of the APT instrument, and the support stage 1 is fixed to the sample holder through cooperative engagement between a positioning pin configured on the sample holder and the positioning surface 621 on the second base column segment.

### II. In-Situ TEM-APT Testing

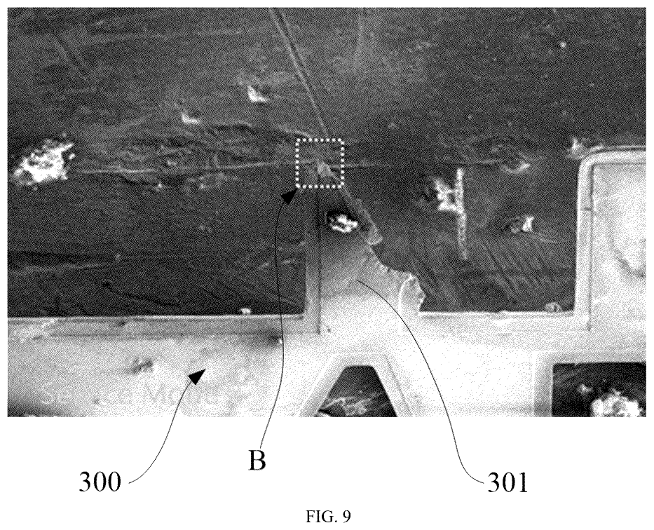

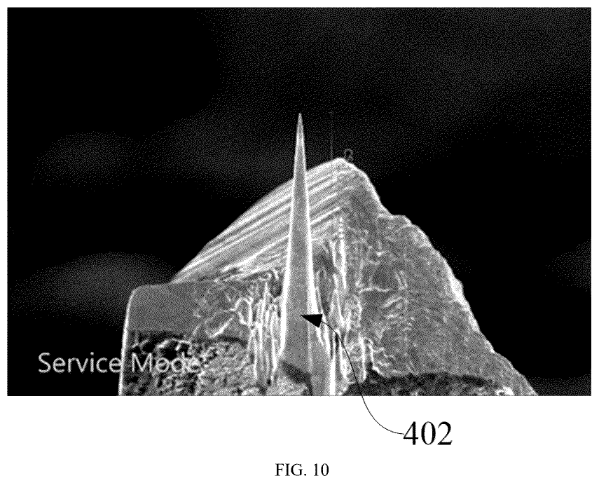

With primary reference to FIGS. 9-10, the metal support grid 300 is provided with multiple comb-shaped teeth 301. A second specimen (needle-shaped specimen) 402 prepared by FIB is bonded to tip portions of the comb-shaped teeth 301.

When performing in-situ TEM-APT testing using the aforementioned multifunctional sample stage 100, TEM microscopic structural analysis may first be conducted on the FIB-prepared needle-shaped specimen. Subsequently, the specimen may be extracted and transferred to the APT instrument for three-dimensional reconstruction characterization of elements. Finally, TEM results may be correlated with atom probe data to obtain comprehensive information including morphology, crystal structure, chemical composition, and atomic occupancy states at identical specimen locations. Specifically, the in-situ TEM-APT testing procedure comprises:
first, placing the concave sample stage 31 on the second-step tier 12 of the support stage 1 and fixing the concave sample stage 31 to the support stage 1 using a third fastener (not shown) such as screws;
then, vertically positioning the metal support grid 300 carrying the second specimen 402 at the recessed mounting position 311 of the concave sample stage 31; These second specimens 402 specimens were previously analyzed by TEM; and
finally, placing the convex fixing stage 32 on the second-step tier 12 of the support stage 1, engaging the convex fixing stage 32 with the concave sample stage 31, and fixedly connecting the convex fixing stage 32 and the concave sample stage 31 using a second fastener such as screws. In the fixed state, the protruding end 321 of the convex fixing stage 32 extends into the recessed mounting position 311 of the concave sample stage 31 and abuts against the metal support grid 300 positioned at the vertical surface 312.

For APT testing, the support stage carrying the concave sample stage, convex fixing stage, and metal support grid is inserted into the base of the APT instrument for experimentation.

In the present example, the concave sample stage 31 is provided with two recessed mounting positions 311, each having a vertical cross-section comprising a partial semicircle (equivalent to a truncated cone cross-section), with a semicircular diameter of 3 mm. Correspondingly, the convex fixing stage 32 is provided with two protruding ends 321, each having a diameter slightly smaller than the recessed mounting positions (e.g., 2.98 mm) to ensure smooth engagement between the concave sample stage 31 and the convex fixing stage 32.

It can be observed that the multifunctional sample stage for in-situ testing with transmission electron microscope and atom probe tomography according to the present disclosure achieves, in one aspect, placement of a silicon wafer carrying needle-shaped specimens to enable conventional APT testing. Based on conventional APT testing, spatial composition reconstruction information of materials across multiple regions is obtained by utilizing the silicon wafer to carry additional needle-shaped specimens. In another aspect, the multifunctional sample stage achieves placement of a metal support grid carrying needle-shaped specimens to enable in-situ TEM-APT analysis. Through in-situ TEM-APT analysis, comprehensive material characteristics including morphological images, crystal structures, atomic occupancy, elemental valence states, major elemental compositions, and three-dimensional spatial distribution of elements are obtained. The configuration fulfills testing requirements for both functions through implementation of a single sample stage apparatus, effectively reducing costs. Further, the multifunctional sample stage of the present disclosure provides advantages of easy fixation/removal of the metal support grid and stable transfer of specimens between TEM and APT instruments. Specifically, the configuration effectively prevents damage to fragile needle-shaped specimens while offering operational simplicity and easy disassembly.

What is claimed is:

1. A multifunctional sample stage for in-situ testing with transmission electron microscope and atom probe tomography, comprising:
a support stage comprising a base body, the base body having a first-step tier and a second-step tier;
a metal pressing plate, wherein a first portion of the metal pressing plate is fixed to the first-step tier, and a second portion of the metal pressing plate is engageable with a silicon wafer carrying specimens disposed on the second-step tier;
and a sample mounting stage assembly positionable on the second-step tier, wherein a metal support grid for carrying specimens is capable of being fixed to the sample mounting stage assembly;
wherein, the sample mounting stage assembly comprises:
a concave sample stage having formed thereon at least one recessed mounting position, the concave sample stage comprising a vertical surface at a location corresponding to the recessed mounting position, wherein a metal support grid carrying specimens is positionable at the recessed mounting position adjacent to the vertical surface;
and a convex fixing stage having formed thereon a protruding end engageable with the recessed mounting position,
wherein the protruding end is capable of being inserted into the corresponding recessed mounting position to clamp the specimen-carrying metal support grid between the protruding end and the vertical surface.

2. The multifunctional sample stage for in-situ testing with transmission electron microscope and atom probe tomography according to claim 1, wherein the concave sample stage and the convex fixing stage are fixedly connected by a second fastener.

3. The multifunctional sample stage for in-situ testing with transmission electron microscope and atom probe tomography according to claim 1, wherein the concave sample stage and/or the convex fixing stage are fixedly connected to the second-step tier by a third fastener.

4. The multifunctional sample stage for in-situ testing with transmission electron microscope and atom probe tomography according to claim 1, wherein the recessed mounting position has a vertical cross-section comprising an inverted semicircle or an isosceles trapezoid,
wherein the legs of the isosceles trapezoid are arc-shaped.

5. The multifunctional sample stage for in-situ testing with transmission electron microscope and atom probe tomography according to claim 1, wherein the metal pressing plate comprises a first pressing portion and a second pressing portion,
wherein the first pressing portion is disposed on the first-step tier, and an end of the second pressing portion adjacent to the silicon wafer is lower than an end of the second pressing portion adjacent to the first pressing portion.

6. The multifunctional sample stage for in-situ testing with transmission electron microscope and atom probe tomography according to claim 5, wherein the second pressing portion comprises a sloped surface portion and/or a curved surface portion.

7. The multifunctional sample stage for in-situ testing with transmission electron microscope and atom probe tomography according to claim 6, wherein the first pressing portion is fixed to the first-step tier by a first fastener; and/or
the support stage is provided with a limiting structure at a position corresponding to the first-step tier.

8. The multifunctional sample stage for in-situ testing with transmission electron microscope and atom probe tomography according to claim 1, wherein the sample stage comprises a base column disposed at the bottom portion of the support stage, the base column being configured to engage with a sample holder of an APT instrument.

9. The multifunctional sample stage for in-situ testing with transmission electron microscope and atom probe tomography according to claim 8, wherein the base column comprises a first base column segment and a second base column segment arranged sequentially from top to bottom,
wherein a radial dimension of the first base column segment is greater than a radial dimension of the second base column segment; and/or
the second base column segment has a circular or D-shaped cross-section.
